(19) United States
(12) Patent Application Publication
(10) Pub. No.: US 2026/0291173 A1
(43) Pub. Date: Sep. 24, 2026

(54) LIGHT-EMITTING DEVICE

(71) Applicant: Kabushiki Kaisha Toshiba, Kawasaki-shi (JP)

(72) Inventors: Shinji SAITO, Yokohama Kanagawa (JP); Tsutomu KAKUNO, Fujisawa Kanagawa (JP); Rei HASHIMOTO, Edogawa Tokyo (JP); Kei KANEKO, Yokohama Kanagawa (JP); Tetsuya MIYAGAWA, Yokohama Kanagawa (JP)

(21) Appl. No.: 19/542,487

(22) Filed: Feb. 17, 2026

(30) Foreign Application Priority Data
Mar. 19, 2025 (JP) 2025-044224

(51) Int. Cl. H01S 5/042; H01S 5/11

(52) U.S. Cl. CPC H01S 5/0425; H01S 5/11

(57) ABSTRACT

According to one embodiment, a light-emitting device includes a first conductive member including an opening, a second conductive member, a semiconductor laser element, and a fixing member. The semiconductor laser element is provided between the second conductive member and the first conductive member. The semiconductor laser element includes a first electrode, a second electrode, and a semiconductor member. The semiconductor laser element includes a first face. The first electrode is provided on the first face. The semiconductor laser element is configured to pass light emitted from the semiconductor member through the first face and the opening. The fixing member causes the second conductive member and the semiconductor laser element to be in contact with each other, and cause the first conductive member and the semiconductor laser element to be in contact with each other.

### CROSS-REFERENCE TO RELATED APPLICATIONS

This application is based upon and claims the benefit of priority from Japanese Patent Application No. 2025-044224, filed on March 19, 2025; the entire contents of which are incorporated herein by reference.

### FIELD

Embodiments described herein relate generally to a light-emitting device.

### BACKGROUND

For example, in light-emitting devices using lasers and the like, improvements in characteristics are desired.

### BRIEF DESCRIPTION OF THE DRAWINGS

FIGS. 1A and 1B are schematic views illustrating a light-emitting device according to a first embodiment;

FIG. 2 is a schematic cross-sectional view illustrating the light-emitting device according to the first embodiment;

FIG. 3 is a schematic cross-sectional view illustrating a light-emitting device according to the first embodiment;

FIG. 4 is a schematic cross-sectional view illustrating a light-emitting device according to the first embodiment;

FIG. 5 is a schematic cross-sectional view illustrating a light-emitting device according to the first embodiment;

FIG. 6 is a schematic cross-sectional view illustrating a light-emitting device according to the first embodiment;

FIG. 7 is a schematic cross-sectional view illustrating a light-emitting device according to the first embodiment;

FIG. 8 is a schematic plan view illustrating a light-emitting device according to the first embodiment;

FIG. 9 is a schematic cross-sectional view illustrating a light-emitting device according to a second embodiment; and

FIG. 10 is a schematic cross-sectional view illustrating a part of a light-emitting device according to an embodiment.

### DETAILED DESCRIPTION

According to one embodiment, a light-emitting device includes a first conductive member including an opening, a second conductive member, a semiconductor laser element, and a fixing member. The semiconductor laser element is provided between the second conductive member and the first conductive member. The semiconductor laser element includes a first electrode, a second electrode, and a semiconductor member provided between the second electrode and the first electrode. In a first direction from the second conductive member to the first conductive member, the second electrode is between the second conductive member and the semiconductor member. In the first direction, the first electrode is between the semiconductor member and the first conductive member. The semiconductor laser element includes a first face. The first electrode is provided on the first face. The semiconductor laser element is configured to pass light emitted from the semiconductor member through the first face and the opening. The fixing member causes the second conductive member and the semiconductor laser element to be in contact with each other, and cause the first conductive member and the semiconductor laser element to be in contact with each other.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

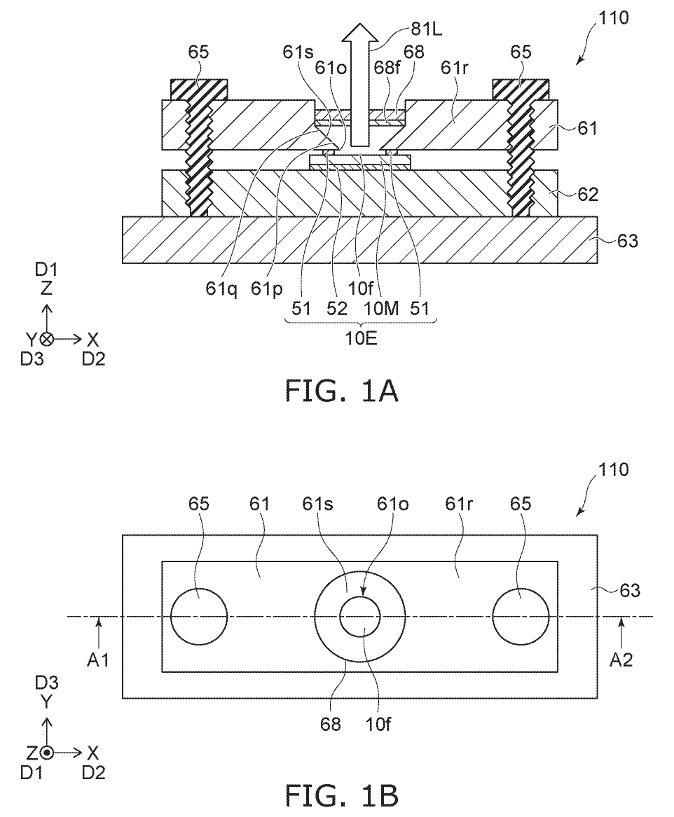

FIGS. 1A and 1B are schematic views illustrating a light-emitting device according to a first embodiment.

FIG. 1A is a cross-sectional view taken along the line A1-A2 in FIG. 1B. FIG. 1B is a plan view.

As shown in FIGS. 1A and 1B, a light-emitting device 110 according to the embodiment includes a first conductive member 61, a second conductive member 62, a semiconductor laser element 10E, and a fixing member 65.

The first conductive member 61 includes an opening 61o. The first conductive member 61 includes a first plate-shaped portion 61r around the opening 61o.

The semiconductor laser element 10E is provided between the second conductive member 62 and the first conductive member 61. The semiconductor laser element 10E includes a first electrode 51, a second electrode 52, and a semiconductor member 10M provided between the second electrode 52 and the first electrode 51. In a first direction D1 from the second conductive member 62 to the first conductive member 61, the second electrode 52 is between the second conductive member 62 and the semiconductor member 10M.

The first direction D1 is defined as a Z-axis direction. One direction perpendicular to the Z-axis direction is defined as an X-axis direction. A direction perpendicular to the Z-axis direction and the X-axis direction is defined as a Y-axis direction. The first conductive member 61 and the second conductive member 62 extend, for example, along the X-Y plane.

In the first direction D1, the first electrode 51 is between the semiconductor member 10M and the first conductive member 61. The semiconductor laser element 10E includes a first face 10f on which the first electrode 51 is provided. The semiconductor laser element 10E is configured to pass light 81L emitted from the semiconductor member 10M through the first face 10f and the opening 61o. The semiconductor laser element 10E is, for example, a surface-emitting laser.

The fixing member 65 causes the second conductive member 62, the semiconductor laser element 10E, and the first conductive member 61 to contact with each other. In this example, the fixing member 65 pierces the first conductive member 61 along the first direction D1. The fixing member 65 may also pierce the second conductive member 62 along the first direction D1.

In one example, the fixing member 65 may be a screw or the like. The fixing member 65 applies a force to the first conductive member 61 in the direction toward the second conductive member 62. For example, the fixing member 65 is configured to apply a force to the second conductive member 62 and the first conductive member 61 so that the distance between the second conductive member 62 and the first conductive member 61 along the first direction D1 is shortened. This causes the semiconductor laser element 10E to come into contact with the first conductive member 61 and the second conductive member 62.

For example, the first conductive member 61 may be electrically connected to the first electrode 51. The second conductive member 62 may be electrically connected to the second electrode 52. For example, a current may be supplied to the semiconductor laser element 10E via the first conductive member 61 and the second conductive member 62.

The first conductive member 61 and the second conductive member 62 include a metal. For example, the first conductive member 61 and the second conductive member 62 may be entirely made of a metal. Each of the first conductive member 61 and the second conductive member 62 may include, for example, an insulator and a metal layer provided on the surface of the insulator. As a result, at least the surface portions of these conductive members are conductive.

In the semiconductor laser element 10E to which a current is supplied, light 81L is emitted from the semiconductor member 10M. As already explained, the light 81L is emitted from the first face 10f, passes through the opening 61o, and travels into the external space.

As the light 81L is emitted, heat is generated in the semiconductor laser element 10E. The heat is propagated to the first conductive member 61 and the second conductive member 62 and dissipated. An excessive increase in the temperature of the semiconductor laser element 10E is suppressed. These conductive members function as, for example, a heat sink. Efficient heat dissipation stabilizes the characteristics of the semiconductor laser element 10E. High-output light 81L can be obtained while maintaining good characteristics. According to the embodiment, a light-emitting device capable of improving characteristics can be obtained.

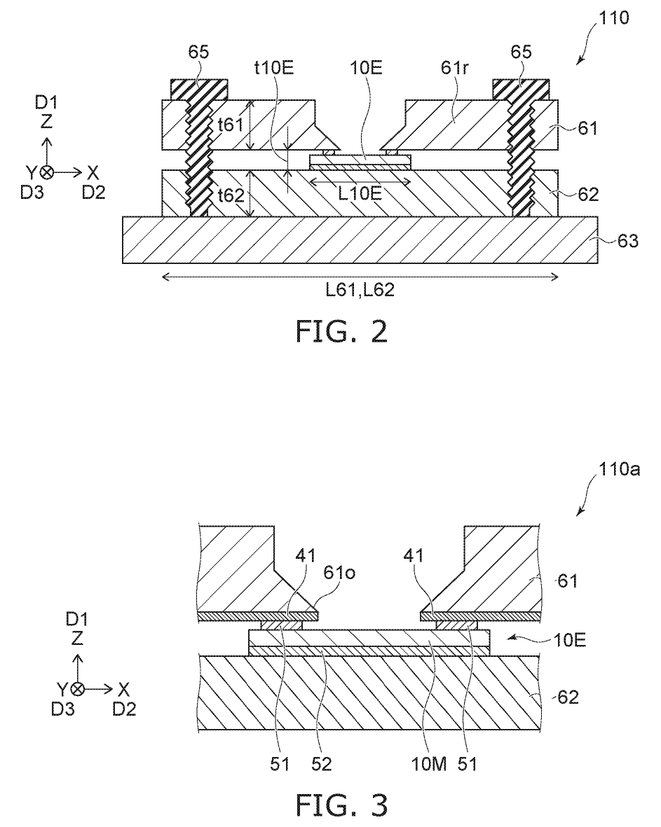

FIG. 2 is a schematic cross-sectional view illustrating the light-emitting device according to the first embodiment.

As shown in FIG. 2, a thickness of the first conductive member 61 in the first direction D1 is defined as a first thickness t61. A thickness of the second conductive member 62 in the first direction D1 is defined as a second thickness t62. A thickness of the semiconductor laser element 10E in the first direction D1 is defined as a semiconductor laser element thickness t10E. The first thickness t61 may be 10 times or more the semiconductor laser element thickness t10E. The second thickness t62 may be 10 times or more the semiconductor laser element thickness t10E.

A length of the first conductive member 61 in the second direction D2 is defined as a first length L61. The second direction D2 crosses the first direction D1. The second direction D2 is, for example, the X-axis direction. A length of the second conductive member 62 in the second direction D2 is defined as a second length L62. A length of the semiconductor laser element 10E in the second direction D2 is defined as a semiconductor laser element length L10E. The first length L61 may be 10 times or more the semiconductor laser element length L10E. The second length L62 may be 10 times or more the semiconductor laser element length L10E.

The above length may be the length in a third direction D3. The third direction D3 crosses a plane including the first direction D1 and the second direction D2. The third direction D3 may be, for example, the Y-axis direction.

For example, the volume of each of the first conductive member 61 and the second conductive member 62 is sufficiently larger than the volume of the semiconductor laser element 10E. Efficient heat dissipation is obtained.

The first thickness t61 may be 100 times or more the semiconductor laser element thickness t10E. The second thickness t62 may be 100 times or more the semiconductor laser element thickness t10E. The first length L61 may be 100 times or more the semiconductor laser element length L10E. The second length L62 may be 100 times or more the semiconductor laser element length L10E.

As shown in FIG. 1A, the first conductive member 61 includes a side face 61s of the opening 61o. The side face 61s crosses a plane (X-Y plane) that crosses the first direction D1. At least a part of the side face 61s may be inclined with respect to the first direction D1.

For example, the side face 61s includes a first portion 61p and a second portion 61q. A first position of the first portion 61p in the first direction D1 is between a position of the second conductive member 62 in the first direction D1 and a second position of the second portion 61q in the first direction D1. The width (second width) of the second portion 61q of the opening 61o is larger than the width (first width) of the first portion 61p of the opening 61o. The width is, for example, a length along a second direction D2 that crosses the first direction D1. The second direction D2 may be, for example, the X-axis direction. The width of the opening 61o increases in the direction from the second conductive member 62 to the first conductive member 61. The opening 61o having such a shape allows the light 81L to be emitted to the outside with low loss.

As shown in FIG. 1A, the light-emitting device 110 may further include an optical member 68. The optical member 68 is provided in the opening 61o. The optical member 68 transmits the light 81L. The optical member 68 may function, for example, as a protective member. As described later, the light 81L may include infrared light. In this case, the optical member 68 may include, for example, at least one selected from the group consisting of Ge, Si, and ZnSe.

The optical member 68 may include an optical multilayer film 68f. The optical multilayer film 68f may include a plurality of first films and a plurality of second films. One of the pluralities of first films is between one of the pluralities of second films and another one of the pluralities of second films. One of the pluralities of second films is between one of the pluralities of first films and another one of the pluralities of first films. The refractive index of the first films is different from the refractive index of the second films. The optical multilayer film 68f effectively reflects or transmits the light 81L. The optical multilayer film 68f appropriately interferes with the light 81L, and the intensity of the light 81L may be enhanced.

The fixing member 65 may be, for example, insulating. In this example, the light-emitting device 110 includes a substrate 63. A second conductive member 62 is fixed to the substrate 63.

In the embodiment, at least one of the first conductive member 61 and the second conductive member 62 includes, for example, at least one selected from the group consisting of Cu, CuW, and a carbon laminate. A stable shape and low electrical resistance are obtained.

FIG. 3 is a schematic cross-sectional view illustrating a light-emitting device according to the first embodiment.

As shown in FIG. 3, a light-emitting device 110a according to the embodiment further includes a first intermediate conductive member 41. The configuration of the light-emitting device 110a except for this may be the same as the configuration of the light-emitting device 110.

In the light-emitting device 110a, the first intermediate conductive member 41 is provided between the first conductive member 61 and the semiconductor laser element 10E. The hardness of the first intermediate conductive member 41 is lower than the first hardness of the first conductive member 61. The first intermediate conductive member 41 is easily deformed. By providing the first intermediate conductive member 41, a more stable electrical connection between the first electrode 51 and the first conductive member 61 can be obtained.

The first intermediate conductive member 41 includes at least one selected from the group consisting of In, Ga, Al, Sn, and C.

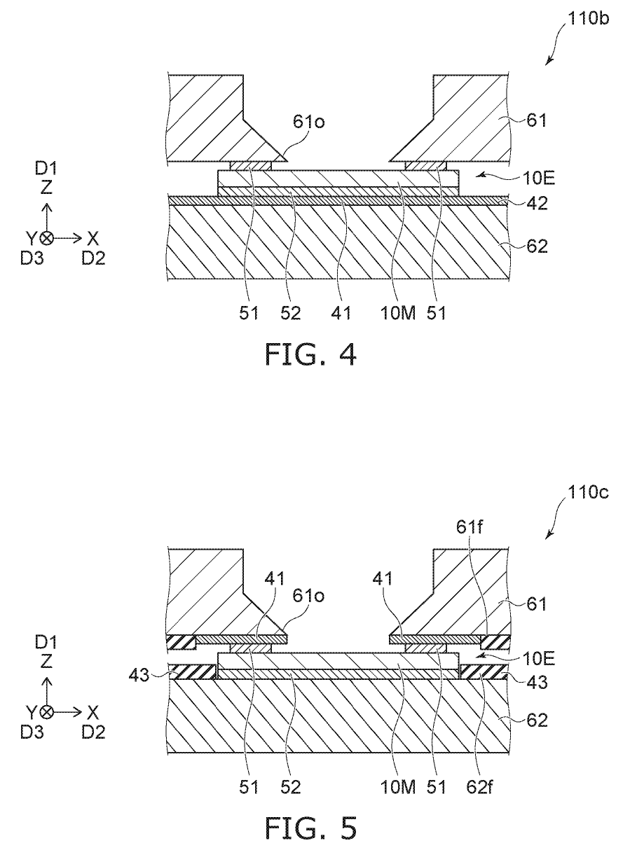

FIG. 4 is a schematic cross-sectional view illustrating a light-emitting device according to the first embodiment.

As shown in FIG. 4, a light-emitting device 110b according to the embodiment further includes a second intermediate conductive member 42. The configuration of the light-emitting device 110b except for this may be the same as the configuration of the light-emitting device 110.

In the light-emitting device 110b, the second intermediate conductive member 42 is provided between the second conductive member 62 and the semiconductor laser element 10E. The hardness of the second intermediate conductive member 42 is lower than the second hardness of the second conductive member 62. A more stable electrical connection is obtained between the second electrode 52 and the second conductive member 62. The second intermediate conductive member 42 may include, for example, at least one selected from the group consisting of In, Ga, Al, Sn, and C.

FIG. 5 is a schematic cross-sectional view illustrating a light-emitting device according to the first embodiment.

As shown in FIG. 5, a light-emitting device 110c according to the embodiment further includes an insulating layer 43. The configuration of the light-emitting device 110c except for this may be the same as the configuration of the light-emitting device 110.

In the light-emitting device 110c, the first conductive member 61 includes a first conductive member face 61f that faces the second conductive member 62. The second conductive member 62 includes a second conductive member face 62f that faces the first conductive member 61. The insulating layer 43 is provided on at least one of the first conductive member face 61f and the second conductive member face 62f. By the insulating layer 43, it is suppressed that the first conductive member 61 and the second conductive member 62 directly contacts each other and a current flow between them. The insulating layer 43 does not overlap the semiconductor laser element 10E in the first direction D1, for example.

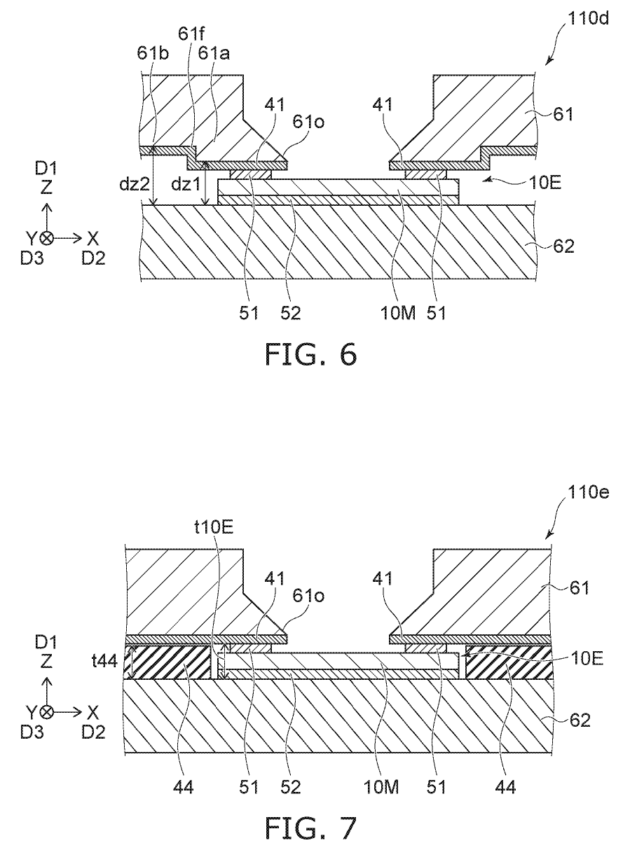

FIG. 6 is a schematic cross-sectional view illustrating a light-emitting device according to the first embodiment.

As shown in FIG. 6, in a light-emitting device 110d according to the embodiment, the shape of the first conductive member 61 is different from that in the light-emitting device 110. The configuration of the light-emitting device 110d except for this may be the same as the configuration of the light-emitting device 110 or the like.

In the light-emitting device 110d, the first conductive member 61 includes a first partial region 61a and a second partial region 61b. The first partial region 61a is between the second partial region 61b and the opening 61o in a direction (e.g., the second direction D2) crossing the first direction D1. A second distance dz2 in the first direction D1 between the second conductive member 62 and the second partial region 61b is longer than a first distance dz1 in the first direction D1 between the second conductive member 62 and the first partial region 61a.

For example, a step is provided on the first conductive member face 61f of the first conductive member 61. By the difference in distance, it is suppressed that the second conductive member 62 and the first conductive member 61 come into contact with each other.

FIG. 7 is a schematic cross-sectional view illustrating a light-emitting device according to the first embodiment.

As shown in FIG. 7, the light-emitting device 110e according to the embodiment further includes a first intermediate insulating member 44. The configuration of the light-emitting device 110e except for this may be the same as the configuration of the light-emitting device 110 and the like.

In the light-emitting device 110e, the first intermediate insulating member 44 is located between the second conductive member 62 and the first conductive member 61. The first intermediate insulating member 44 does not overlap the semiconductor laser element 10E in the first direction D1. The direction from the first intermediate insulating member 44 to the semiconductor laser element 10E crosses the first direction D1.

The first intermediate insulating member 44 functions as, for example, a spacer. For example, the position of the semiconductor laser element 10E is stably controlled.

For example, a thickness of the first intermediate insulating member 44 along the first direction D1 is defined as a first intermediate insulating member thickness t44. A thickness of the semiconductor laser element 10E along the first direction D1 is defined as a semiconductor laser element thickness t10E. The first intermediate insulating member thickness t44 is equal to or smaller than the semiconductor laser element thickness t10E.

The first intermediate insulating member thickness t44 may be thinner than the semiconductor laser element thickness t10E. In this case, the difference between the first intermediate insulating member thickness t44 and the semiconductor laser element thickness t10E may be equal to or smaller than 10μm.

In the various light-emitting elements described above, the number of fixing members 65 may be two. The number of fixing members 65 may be three or more.

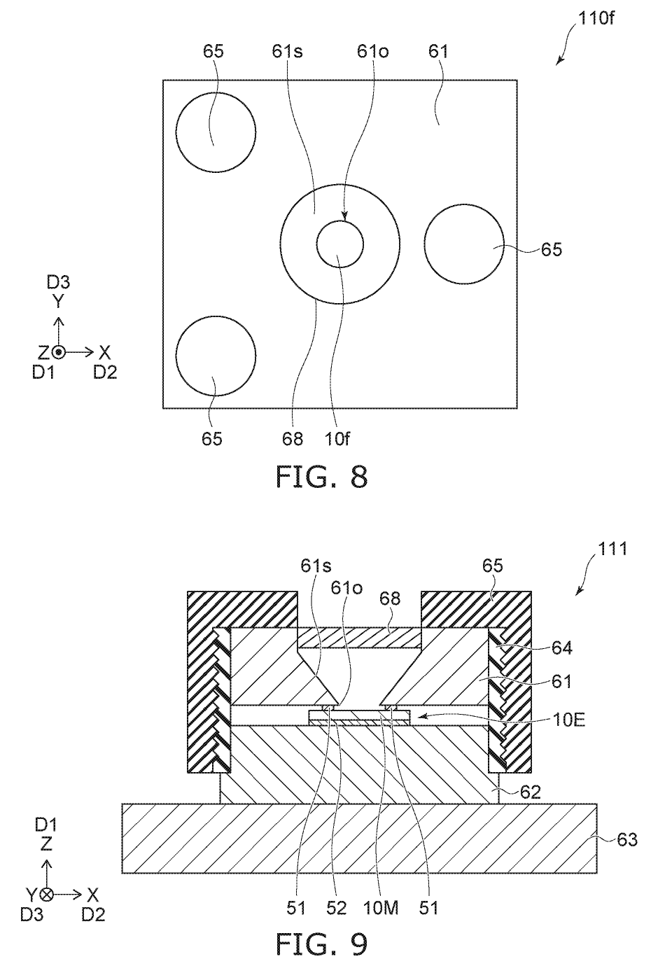

FIG. 8 is a schematic plan view illustrating a light-emitting device according to the first embodiment.

As shown in FIG. 8, a light-emitting device 110f according to the embodiment has three fixing members 65. The configuration of the light-emitting device 110f except for this may be the same as the configuration of the light-emitting device 110 and the like.

### Second Embodiment

FIG. 9 is a schematic cross-sectional view illustrating a light-emitting device according to the second embodiment.

As shown in FIG. 9, in a light-emitting device 111 according to the embodiment, the fixing members 65 have a different configuration from the configuration of the fixing members 65 in the first embodiment. The configuration of the light-emitting device 111 except for this may be the same as the configuration of the light-emitting device 110 and the like.

In the light-emitting device 111, the fixing member 65 may have a screw thread on the inside of the side of the fixing member 65 around the first conductive member 61 and the second conductive member 62 in a direction crossing the first direction D1. For example, an insulating member 64 may be provided between the first conductive member 61 and the side of the fixing member 65, and between the second conductive member 62 and the side of the fixing member 65. The screw thread on the side of the fixing member 65 and the screw thread on the outer side of the insulating member 64 mesh with each other. For example, by rotating the fixing member 65, a force is applied to the first conductive member 61 and the second conductive member 62. A stable connection is obtained.

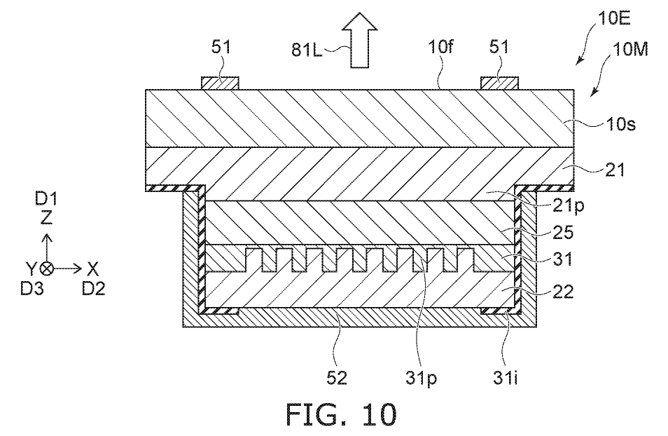

FIG. 10 is a schematic cross-sectional view illustrating a part of a light-emitting device according to an embodiment.

FIG. 10 illustrates the semiconductor laser element 10E. As shown in FIG. 10 , the semiconductor laser element 10E includes the first electrode 51, the second electrode 52, and the semiconductor member 10M. The semiconductor member 10M includes a first cladding layer 21, a second cladding layer 22, a light-emitting layer 25, and a photonic crystal layer 31.

The first cladding layer 21 is provided between the first electrode 51 and the second electrode 52. The second cladding layer 22 is provided between the first cladding layer 21 and the second electrode 52. The light-emitting layer 25 is provided between the first cladding layer 21 and the second cladding layer 22. The photonic crystal layer 31 is provided between the light-emitting layer 25 and the second cladding layer 22.

Light 81L is emitted from the light-emitting layer 25 by a current supplied to the light-emitting layer 25 via the first electrode 51 and the second electrode 52. The traveling direction of the light 81L being emitted is changed in the photonic crystal layer 31, and the light 81L is emitted from the first face 10f.

For example, the light-emitting layer 25 may emit light by intersubband transition. The semiconductor laser element 10E may be, for example, a surface-emitting quantum cascade laser (QCL).

The peak wavelength of the light 81L may be, for example, not less than 240nm and not more than 30μm. The peak wavelength of the light 81L may be, for example, not less than 1000nm and not more than 10μm. The light 81L may be, for example, infrared light. The light 81L may be, for example, near-infrared light or visible light.

In one example, the first cladding layer 21 may include In and P. The second cladding layer 22 may include, for example, In and P. The light-emitting layer 25 may include, for example, at least one selected from the group consisting of InGaAs and InAlAs. At least a part of the photonic crystal layer 31 may include In, Ga, and As.

The photonic crystal layer 31 includes a plurality of protrusions 31p. In this example, a part of the second cladding layer 22 is present between the plurality of protrusions 31p. The refractive index of the plurality of protrusions 31p is different from the refractive index of the second cladding layer 22. There may be a gap (for example, air) between the plurality of protrusions 31p.

The light-emitting layer 25 may be provided between a part of the first cladding layer 21 and the second cladding layer 22. In this example, the semiconductor laser element 10E may include a base 10s. The first cladding layer 21 is between the light-emitting layer 25 and the base 10s.

A part of the second electrode 52 may face a side face of the semiconductor member 10M. An insulating film 31i may be provided between a part of the second electrode 52 and the side face of the semiconductor member 10M.

The light-emitting device according to the embodiment can be used as a light source for, for example, an analytical device. The light-emitting device may be applied to, for example, a gas sensor. The light-emitting device may be applied to, for example, a processing device such as an electronic drawing device.

The embodiments may include the following Technical proposals:

### Technical Proposal 1

A light-emitting device, comprising:
a first conductive member including an opening;
a second conductive member;
a semiconductor laser element provided between the second conductive member and the first conductive member; and a fixing member, the semiconductor laser element including a first electrode, a second electrode, and a semiconductor member provided between the second electrode and the first electrode;
in a first direction from the second conductive member to the first conductive member, the second electrode being between the second conductive member and the semiconductor member,
in the first direction, the first electrode being between the semiconductor member and the first conductive member, the semiconductor laser element including a first face,
the first electrode being provided on the first face, the semiconductor laser element being configured to pass light emitted from the semiconductor member through the first face and the opening; and
the fixing member causing the second conductive member and the semiconductor laser element to be in contact with each other, and causing the first conductive member and the semiconductor laser element to be in contact with each other.

### Technical Proposal 2

The light-emitting device according to Technical proposal 1, further comprising:
a first intermediate conductive member,
the first intermediate conductive member being provided between the first conductive member and the semiconductor laser element, and
a hardness of the first intermediate conductive member is lower than a first hardness of the first conductive member.

### Technical Proposal 3

The light-emitting device according to Technical proposal 2, wherein
the first intermediate conductive member includes at least one selected from the group consisting of In, Ga, Al, Sn, and C.

### Technical Proposal 4

The light-emitting device according to Technical proposal 1, further comprising:
a second intermediate conductive member,
the second intermediate conductive member being provided between the second conductive member and the semiconductor laser element, and
a hardness of the second intermediate conductive member is lower than a second hardness of the second conductive member.

### Technical Proposal 5

The light-emitting device according to Technical proposal 4, wherein
the second intermediate conductive member includes at least one selected from the group consisting of In, Ga, Al, Sn, and C.

### Technical proposal 6

The light-emitting device according to any one of Technical proposals 1-5, further comprising:
a first intermediate insulating member,
the first intermediate insulating member being between the second conductive member and the first conductive member, and
a direction from the first intermediate insulating member to the semiconductor laser element crosses the first direction.

### Technical Proposal 7

The light-emitting device according to Technical proposal 6, wherein
a first intermediate insulating member thickness of the first intermediate insulating member along the first direction is equal to or less than a semiconductor laser element thickness of the semiconductor laser element along the first direction.

### Technical Proposal 8

The light-emitting device according to Technical proposal 6, wherein
a first intermediate insulating member thickness of the first intermediate insulating member along the first direction is thinner than a semiconductor laser element thickness of the semiconductor laser element along the first direction, and
a difference between the first intermediate insulating member thickness and the semiconductor laser element thickness is 10 μm or less.

### Technical Proposal 9

The light-emitting device according to any one of Technical proposals 1-6, wherein
a first thickness of the first conductive member in the first direction is 10 times or more a semiconductor laser element thickness of the semiconductor laser element in the first direction,
a first length of the first conductive member in a second direction crossing the first direction is 10 times or more a semiconductor laser element length of the semiconductor laser element in the second direction,
a second thickness of the second conductive member in the first direction is 10 times or more the semiconductor laser element thickness, and
a second length of the second conductive member in the second direction is 10 times or more the semiconductor laser element length.

### Technical Proposal 10

The light-emitting device according to any one of Technical proposals 1-9, further comprising:
an insulating layer,
the first conductive member including a first conductive member face facing the second conductive member,
the second conductive member including a second conductive member face facing the first conductive member, and
the insulating layer being provided on at least one of the first conductive member face and the second conductive member face.

### Technical Proposal 11

The light-emitting device according to any one of Technical proposals 1-10, wherein
the first conductive member includes a first partial region and a second partial region,
the first partial region is between the second partial region and the opening in a direction crossing the first direction, and
a second distance in the first direction between the second conductive member and the second partial region is longer than a first distance in the first direction between the second conductive member and the first partial region.

### Technical Proposal 12

The light-emitting device according to any one of Technical proposals 1-11, wherein
the first conductive member includes a side face of the opening,
the side face includes a first portion and a second portion,
a first position of the first portion in the first direction is between a position of the second conductive member in the first direction and
a second position of the second portion in the first direction, and a second width of the opening in the second portion is larger than a first width of the opening in the first portion.

### Technical Proposal 13

The light-emitting device according to Technical proposal 12, wherein
at least a part of the side face is inclined with respect to the first direction.

### Technical Proposal 14

The light-emitting device according to any one of Technical proposals 1-13, wherein
the fixing member is configured to apply a force to the second conductive member and the first conductive member so that a distance between the second conductive member and the first conductive member along the first direction is shortened.

### Technical Proposal 15

The light-emitting device according to any one of Technical proposals 1-14, further comprising:
an optical member provided in the opening,
the optical member including an optical multilayer film,
the light emitted from the semiconductor member passes through the optical member and is emitted to outside, and
the fixing member is configured to control the gap between the semiconductor laser element and the optical member.

### Technical Proposal 16

The light-emitting device according to any one of Technical proposals 1-15, wherein
the semiconductor member includes:
   a first clad layer provided between the first electrode and the second electrode;
a second clad layer provided between the first clad layer and the second electrode;
a light-emitting layer provided between the first clad layer and the second clad layer; and
a photonic crystal layer provided between the light-emitting layer and the second clad layer.

### Technical Proposal 17

The light-emitting device according to Technical proposal 16, wherein
the first cladding layer includes In and P,
the second cladding layer includes In and P,
the light-emitting layer includes at least one selected from the group consisting of InGaAs and InAlAs, and
at least a part of the photonic crystal layer includes In, Ga, and As.

### Technical Proposal 18

The light-emitting device according to Technical proposal 17, wherein
the photonic crystal layer includes a plurality of protrusions,
a part of the second cladding layer is present between the plurality of protrusions, and a
refractive index of the plurality of protrusions is different from a refractive index of the second cladding layer.

### Technical Proposal 19

The light-emitting device according to any one of Technical proposals 16-18, wherein
the light-emitting layer emits light based on intersubband transition.

### Technical Proposal 20

The light-emitting device according to any one of Technical proposals 1 to 18, wherein
a peak wavelength of the light is not less than 240 nm and not more than 30 μm.
According to the embodiment, a light-emitting device can be provided that can improve characteristics.
In the specification, "vertical" and "parallel" do not only mean strictly vertical and strictly parallel, but also include, for example, variations in the manufacturing process, and may mean substantially vertical and substantially parallel.
Hereinabove, exemplary embodiments of the invention are described with reference to specific examples. However, the embodiments of the invention are not limited to these specific examples. For example, one skilled in the art may similarly practice the invention by appropriately selecting specific configurations of components included in the light-emitting devices such as conductive members, fixing members, semiconductor laser elements, electrodes, cladding layers, light-emitting layers, etc., from known art. Such practice is included in the scope of the invention to the extent that similar effects thereto are obtained.
Further, any two or more components of the specific examples may be combined within the extent of technical feasibility and are included in the scope of the invention to the extent that the purport of the invention is included.
Moreover, all light-emitting devices practicable by an appropriate design modification by one skilled in the art based on the light-emitting devices described above as embodiments of the invention also are within the scope of the invention to the extent that the purport of the invention is included.
Various other variations and modifications can be conceived by those skilled in the art within the spirit of the invention, and it is understood that such variations and modifications are also encompassed within the scope of the invention.
While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light-emitting device, comprising:
a first conductive member including an opening;
a second conductive member;
a semiconductor laser element provided between the second conductive member and the first conductive member; and a fixing member,
the semiconductor laser element including a first electrode, a second electrode, and a semiconductor member provided between the second electrode and the first electrode;
in a first direction from the second conductive member to the first conductive member, the second electrode being between the second conductive member and the semiconductor member,
in the first direction, the first electrode being between the semiconductor member and the first conductive member,
the semiconductor laser element including a first face, the first electrode being provided on the first face,
the semiconductor laser element being configured to pass light emitted from the semiconductor member through the first face and the opening; and
the fixing member causing the second conductive member and the semiconductor laser element to be in contact with each other and causing the first conductive member and the semiconductor laser element to be in contact with each other.

2. The light-emitting device according to claim 1, further comprising:
a first intermediate conductive member,
the first intermediate conductive member being provided between the first conductive member and the semiconductor laser element, and
a hardness of the first intermediate conductive member is lower than a first hardness of the first conductive member.

3. The light-emitting device according to claim 2, wherein
the first intermediate conductive member includes at least one selected from the group consisting of In, Ga, Al, Sn, and C.

4. The light-emitting device according to claim 1, further comprising:
a second intermediate conductive member,
the second intermediate conductive member being provided between the second conductive member and the semiconductor laser element, and
a hardness of the second intermediate conductive member is lower than a second hardness of the second conductive member.

5. The light-emitting device according to claim 4, wherein
the second intermediate conductive member includes at least one selected from the group consisting of In, Ga, Al, Sn, and C.

6. The light-emitting device according to claim 1, further comprising:
a first intermediate insulating member,
the first intermediate insulating member being between the second conductive member and the first conductive member, and
a direction from the first intermediate insulating member to the semiconductor laser element crosses the first direction.

7. The light-emitting device according to claim 6, wherein
a first intermediate insulating member thickness of the first intermediate insulating member along the first direction is equal to or less than a semiconductor laser element thickness of the semiconductor laser element along the first direction.

8. The light-emitting device according to claim 6, wherein
a first intermediate insulating member thickness of the first intermediate insulating member along the first direction is thinner than a semiconductor laser element thickness of the semiconductor laser element along the first direction, and
a difference between the first intermediate insulating member thickness and the semiconductor laser element thickness is 10 μm or less.

9. The light-emitting device according to claim 1, wherein
a first thickness of the first conductive member in the first direction is 10 times or more a semiconductor laser element thickness of the semiconductor laser element in the first direction,
a first length of the first conductive member in a second direction crossing the first direction is 10 times or more a semiconductor laser element length of the semiconductor laser element in the second direction,
a second thickness of the second conductive member in the first direction is 10 times or more the semiconductor laser element thickness, and
a second length of the second conductive member in the second direction is 10 times or more the semiconductor laser element length.

10. The light-emitting device according to claim 1, further comprising:
an insulating layer,
the first conductive member including a first conductive member face facing the second conductive member,
the second conductive member including a second conductive member face facing the first conductive member, and
the insulating layer being provided on at least one of the first conductive member face and the second conductive member face.

11. The light-emitting device according to claim 1, wherein
the first conductive member includes a first partial region and a second partial region,
the first partial region is between the second partial region and the opening in a direction crossing the first direction, and
a second distance in the first direction between the second conductive member and the second partial region is longer than a first distance in the first direction between the second conductive member and the first partial region.

12. The light-emitting device according to claim 1, wherein
the first conductive member includes a side face of the opening,
the side face includes a first portion and a second portion,
a first position of the first portion in the first direction is between a position of the second conductive member in the first direction and a second position of the second portion in the first direction, and
a second width of the opening in the second portion is larger than a first width of the opening in the first portion.

13. The light-emitting device according to claim 12, wherein
at least a part of the side face is inclined with respect to the first direction.

14. The light-emitting device according to claim 1, wherein
the fixing member is configured to apply a force to the second conductive member and the first conductive member so that a distance between the second conductive member and the first conductive member along the first direction is shortened.

15. The light-emitting device according to claim 1, further comprising:
an optical member provided in the opening,
the optical member including an optical multilayer film,
the light emitted from the semiconductor member passes through the optical member and is emitted to outside, and
the fixing member is configured to control the gap between the semiconductor laser element and the optical member.

16. The light-emitting device according to claim 1, wherein
the semiconductor member includes:
a first clad layer provided between the first electrode and the second electrode;
a second clad layer provided between the first clad layer and the second electrode;
a light-emitting layer provided between the first clad layer and the second clad layer; and
a photonic crystal layer provided between the light-emitting layer and the second clad layer.

17. The light-emitting device according to claim 16, wherein
the first cladding layer includes In and P,
the second cladding layer includes In and P,
the light-emitting layer includes at least one selected from the group consisting of InGaAs and InAlAs, and
at least a part of the photonic crystal layer includes In, Ga, and As.

18. The light-emitting device according to claim 17, wherein
the photonic crystal layer includes a plurality of protrusions,
a part of the second cladding layer is present between the plurality of protrusions, and
a refractive index of the plurality of protrusions is different from a refractive index of the second cladding layer.

19. The light-emitting device according to claim 16, wherein
the light-emitting layer emits light based on intersubband transition.

20. The light-emitting device according to claim 1, wherein
a peak wavelength of the light is not less than 240 nm and not more than 30μm.
